(19) United States
(12) Patent Application Publication
(10) Pub. No.: US 2006/0071282 A1
(43) Pub. Date: Apr. 6, 2006

(54) Semiconductor device and manufacturing method thereof

(76) Inventors: Masaru Kadoshima, Tsukuba (JP); Toshihide Nabatame, Tsukuba (JP); Akira Toriumi, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/242,909

(22) Filed: Oct. 5, 2005

(30) Foreign Application Priority Data
Oct. 5, 2004 (JP) 2004-292420

(51) Int. Cl. H01L 29/94

(52) U.S. Cl. 257/369

(57) ABSTRACT

A structure of a MIS transistor for realizing a CMOS circuit capable of simultaneously achieving the high ON current and the low power consumption is provided. Each of the gate insulators of a n channel MIS transistor and a p channel MIS transistor is composed of a hafnium oxide film. Also, the gate electrode is composed of a Pt silicide film with a ratio of Si atoms to Pt atoms of approximately 1 (PtSiₓ: x=1) in the vicinity of a region in contact with the gate insulator. Also, the gate electrode of the p channel MIS transistor is composed of a Pt silicide film with a ratio of Si atoms to Pt atoms of less than 1 (PtSiₓ: x<1) in the vicinity of a region in contact with the gate insulator. Therefore, the Fermi level pinning of the gate electrode is suppressed.

### CROSS-REFERENCE TO RELATED APPLICATION

The present application claims priority from Japanese Patent Application No. JP 2004-292420 filed on Oct. 5, 2004, the content of which is hereby incorporated by reference into this application.

### TECHNICAL FIELD OF THE INVENTION

The present invention relates to a semiconductor device and a manufacturing method thereof. More particularly, it relates to a technology effectively applied to a semiconductor device in which a n channel MIS transistor and a p channel MIS transistor each having a gate electrode formed on a Hf (hafnium)-based gate insulator are used to form a CMOS (Complementary Metal Oxide Semiconductor) circuit.

### BACKGROUND OF THE INVENTION

Conventionally, in the n channel MOS transistor and the p channel MOS transistor which constitute a CMOS circuit, a silicon oxide film is used as a gate insulator material, and a polycrystalline silicon film or a laminated film (polycide film) obtained by laminating a metal silicide film such as a W (tungsten) silicide film or a Co (cobalt) silicide film on a polycrystalline silicon film is used as a gate electrode material formed on the gate oxide film.

Then, a n type impurity (phosphorus, arsenic or the like) is introduced into the polycrystalline silicon film constituting the gate electrode of the n channel MIS transistor to set the work function (Fermi level) of the gate electrode close to the conduction band of Si (approximately 4.05 eV). By doing so, the threshold voltage is reduced. Meanwhile, a p type impurity (boron or the like) is introduced into the polycrystalline silicon film constituting the gate electrode of the p channel MIS transistor to set the work function of the gate electrode close to the valence band of Si (approximately 5.17 eV). By doing so, the threshold voltage is reduced.

However, along with the miniaturization of the MIS transistors constituting the semiconductor integrated circuit, the thickness of the gate oxide film has been rapidly reduced in recent years. Consequently, when voltage is applied to the gate electrode to turn on the MIS transistor, the influence of the depletion in the gate electrode (polycrystalline silicon film) adjacent to the gate oxide film interface becomes increasingly significant, and the thickness of the gate oxide film is apparently increased. As a result, it becomes difficult to ensure the ON current and the operation speed of the transistor is significantly reduced.

Also, when the thickness of the gate oxide film is reduced, since the electrons pass through the gate oxide film due to the quantum effect called direct tunneling, the leakage current is increased. Furthermore, in the p channel MIS transistor, boron in the gate electrode (polycrystalline silicon film) diffuses in the substrate through the gate oxide film, and the impurity concentration of the channel region is increased. Therefore, the threshold voltage fluctuates.

For its solution, the replacement of the gate insulator material from the silicon oxide to the insulator with a higher dielectric constant (high dielectric constant material) and the replacement of the gate electrode material from the polycrystalline silicon (or polycide) to the metal silicide or metal have been examined (for example, Japanese Patent Laid-Open Publication No. 2004-158593, Japanese Patent Laid-Open Publication No. 2004-152995, US Patent Application Publication No. 2004/0065930A1, U.S. Pat. No. 6,475,908 B1 and U.S. Pat. No. 6,750,519 B2).

This is because, when the high dielectric constant film is used to constitute the gate insulator, the actual physical thickness can be increased by a factor of “dielectric constant of a high dielectric constant film/dielectric constant of a silicon oxide film” without changing the capacitance of the equivalent silicon oxide thickness (EOT), and as a result, the leakage current can be reduced. As a high dielectric constant material, various metal oxides such as Hf (hafnium) oxide and Zr (zirconium) oxide have been examined.

In addition, when a material not containing polycrystalline silicon is used to constitute the gate electrode, the reduction of the ON current due to the depletion and the boron leakage from the gate electrode to the substrate can be prevented.

Japanese Patent Laid-Open Publication No. 2004-158593, Japanese Patent Laid-Open Publication No. 2004-152995, and US Patent Publication No. 2004/0065930 A1 disclose the method of forming a p channel MIS transistor and a n channel MIS transistor. In this method, when forming a n channel MIS transistor and a p channel MIS transistor, after forming a silicon-based gate insulator and further a high dielectric constant film as the gate insulator, a metal film such as Pt (platinum), Ti (titanium), Ni (nickel), Co, Ta (tantalum) or Zr is deposited, and silicon is ion-implanted into one metal film to form metal silicide while masking the other metal film, and then, an electrode of the metal film and an electrode of the metal silicide film are respectively formed. In this case, a material with a high work function is used for the p channel MIS transistor, and a material with a low work function is used for the n channel MIS transistor. Also, FIG. 12 and FIG. 13 of Japanese Patent Laid-Open Publication No. 2004-158593, Japanese Patent Laid-Open Publication No. 2004-152995, and US Patent Publication No. 2004/0065930 A1 disclose that, in the case where the first gate electrode and the second gate electrode are made of metal silicide, the amount of silicon ions implanted into the metal silicide of the first gate electrode is set smaller than the amount of silicon ions implanted into the second gate electrode so as to increase the work function of the second gate electrode.

Also, US Patent Publication No. 2004/0065930 A1, U.S. Pat. No. 6,475,908 B1 and U.S. Pat. No. 6,750,519 B2 disclose the list of the work function of metals. Note that, it is estimated that the work function shown in the list is measured directly from the metal films.

The work function of a gate electrode formed on a silicon-based gate insulator such as a silicon oxide film and a silicon oxynitride film is reflected relatively directly on the electrical characteristics. However, when a high dielectric constant material represented by Hf-based oxide is used for the gate insulator, the effective work function is varied in comparison to the case where the silicon-based gate insulator is used, and it is interpreted as the Fermi level pinning (IEEE TRANSACTIONS ON ELECTRON DEVICES, VOL. 51, NO. 6, JUNE 2004, PP. 971 to 984).

### SUMMARY OF THE INVENTION

The low power consumption design is important in the CMOS circuit, and the reduction of the threshold voltage of the n channel MIS transistor and the p channel MIS transistor is required for its achievement.

Therefore, even when a high dielectric constant film such as a Hf oxide is used as a gate insulator material and metal silicide or metal is used as a gate electrode material, it is necessary to select gate electrode materials with a suitable work function so as to prevent the increase of the threshold voltage in the n channel MIS transistor and the p channel MIS transistor.

In the conventional technology described above, however, the Fermi level pinning in which the effective work function of metal silicide formed on a high dielectric constant film is varied when a high dielectric constant film is used as a gate insulator instead of a silicon oxide film is not considered at all.

For example, Japanese Patent Laid-Open Publication No. 2004-158593 discloses a p channel MISFET in which a gate electrode composed of a laminated film of a W (tungsten) film and a platinum silicide film is formed on a gate insulator made of a hafnium oxide film. Also, it says that “the work function of the platinum silicide and tungsten is about 4.8 to 4.9 eV, which is suitable as the gate electrode of the p channel MISFET” (paragraph 0038 in the specification).

However, according to the examination by the inventors of the present invention, when a gate electrode made of metal silicide such as PtSi or NiSi is formed on a hafnium-based gate insulator, in comparison to the case where the gate electrode is formed on a silicon-based gate insulator, the reduction in effective work function due to the Fermi level pinning has been observed. For example, in the case of the gate electrode made of Pt silicide, the work function thereof on the silicon oxide film is 4.8 to 4.9 eV, whereas the effective work function thereof on the hafnium oxide film is 4.5 to 4.6 eV and the Fermi level pinning in the direction of the conduction band of Si is observed. More specifically, when a Pt silicide film is used to constitute the gate electrode of the p channel MIS transistor having a gate insulator formed of a hafnium oxide film, the threshold voltage of the p channel MIS transistor is increased, and thus, the low power consumption design of the CMOS circuit becomes difficult.

Also, in the case of the gate electrode made of Ni silicide, the work function thereof on the silicon oxide film is 4.6 to 4.7 eV, whereas the effective work function thereof on the hafnium oxide film is 4.4 to 4.5 eV and the shift (Fermi level pinning) in the direction of the conduction band of Si (silicon) is observed. More specifically, the threshold voltage of the p channel MIS transistor is increased even when a Ni silicide film is used to constitute the gate electrode of the p channel MIS transistor having a gate insulator formed of a hafnium oxide film. Therefore, the low power consumption design of the CMOS circuit becomes difficult.

Also, in the conventional technology in which silicon is ion-implanted into a metal film to form a metal silicide film, the peeling and the breakage of a metal film may occur depending on the amount of implanted silicon. Furthermore, when a large amount of silicon is implanted into an insulator region other than the metal film, the insulation efficiency of the insulator is degraded.

An object of the present invention is to provide a technology for realizing a CMOS circuit capable of simultaneously achieving the high ON current and the low power consumption.

The above and other objects and novel characteristics of the present invention will be apparent from the description of this specification and the accompanying drawings.

The typical ones of the inventions disclosed in this application will be briefly described as follows.

The present invention provides a semiconductor device in which a n channel MIS transistor is formed in a first region on a main surface of a semiconductor substrate made of single crystal silicon and a p channel MIS transistor is formed in a second region on the main surface, wherein each of the n channel MIS transistor and the p channel MIS transistor has a gate electrode composed of a metal silicide film formed by solid-phase reaction of a silicon film and a metal film on a gate insulator mainly containing hafnium-based oxide,
the metal silicide film constituting the gate electrode of the n channel MIS transistor has a ratio of silicon atoms to metal atoms of approximately 1 in the vicinity of a region in contact with the gate insulator, and
the metal silicide film constituting the gate electrode of the p channel MIS transistor has a ratio of silicon atoms to metal atoms lower than the ratio of the n channel MIS transistor in the vicinity of a region in contact with the gate insulator.

Also, the present invention provides a method of manufacturing the semiconductor device described above. The method comprises the steps of:
(a) forming a gate insulator mainly containing hafnium oxide on the main surface of the semiconductor substrate;
(b) forming a first silicon gate electrode of the n channel MIS transistor on the gate insulator in the first region and forming a second silicon gate electrode of the p channel MIS transistor on the gate insulator in the second region;
(c) depositing a first insulator with a thickness larger than that of the first and second silicon gate electrodes on the main surface of the semiconductor substrate, and then, planarizing a surface of the first insulator, thereby exposing each surface of the first and second silicon gate electrodes on the surface of the first insulator;
(d) etching each of the first and second silicon gate electrodes exposed on the surface of the first insulator, thereby retreating the surfaces of the first and second silicon gate electrodes below the surface of the first insulator;
(e) after the step (d), laminating a metal film with a thickness almost equal to that of the first and second silicon gate electrodes on each of the first and second silicon gate electrodes;
(f) selectively covering the metal film laminated on the first silicon gate electrode with a second insulator, and then, further laminating a metal film on the metal film laminated on the second silicon gate electrode; and
(g) heating the semiconductor substrate to induce the solid phase reaction between the first and second silicon gate electrodes and the metal film, thereby forming a gate electrode of the n channel MIS transistor composed of a metal silicide film having a ratio of silicon atoms to metal atoms of approximately 1 in the vicinity of a region in contact with the gate insulator, and forming a gate electrode of the p channel MIS transistor composed of a metal silicide film having a ratio of silicon atoms to metal atoms lower than the ratio of the n channel MIS transistor in the vicinity of a region in contact with the gate insulator.

The effect obtained by the representative one of the inventions disclosed in this application will be briefly described as follows.

A metal silicide film with a ratio of silicon atoms to metal atoms of approximately 1 is used to form the gate electrode of the n channel MIS transistor, and a metal silicide film with a ratio of silicon atoms to metal atoms of less than 1 is used to form the gate electrode of the p channel MIS transistor. By doing so, the increase of the threshold voltage of the p channel MIS transistor can be suppressed. Therefore, the CMOS circuit capable of simultaneously achieving the high ON current and the low power consumption can be realized.

### BRIEF DESCRIPTIONS OF THE DRAWINGS

FIG. 1 is a cross-sectional view of a semiconductor substrate showing the manufacturing method of a n channel MIS transistor and a p channel MIS transistor according to an embodiment of the present invention;

FIG. 2 is a cross-sectional view of the semiconductor substrate showing the manufacturing method of the n channel MIS transistor and the p channel MIS transistor subsequent to FIG. 1;

FIG. 3 is a cross-sectional view of the semiconductor substrate showing the manufacturing method of the n channel MIS transistor and the p channel MIS transistor subsequent to FIG. 2;

FIG. 4 is a cross-sectional view of the semiconductor substrate showing the manufacturing method of the n channel MIS transistor and the p channel MIS transistor subsequent to FIG. 3;

FIG. 5 is a cross-sectional view of the semiconductor substrate showing the manufacturing method of the n channel MIS transistor and the p channel MIS transistor subsequent to FIG. 4;

FIG. 6 is a cross-sectional view of the semiconductor substrate showing the manufacturing method of the n channel MIS transistor and the p channel MIS transistor subsequent to FIG. 5;

FIG. 7 is a cross-sectional view of the semiconductor substrate showing the manufacturing method of the n channel MIS transistor and the p channel MIS transistor subsequent to FIG. 6;

FIG. 8 is a cross-sectional view of the semiconductor substrate showing the manufacturing method of the n channel MIS transistor and the p channel MIS transistor subsequent to FIG. 7;

FIG. 9 is a cross-sectional view of the semiconductor substrate showing the manufacturing method of the n channel MIS transistor and the p channel MIS transistor subsequent to FIG. 8;

FIG. 10 is a cross-sectional view of the semiconductor substrate showing the manufacturing method of the n channel MIS transistor and the p channel MIS transistor subsequent to FIG. 9;

FIG. 11 is a cross-sectional view of the semiconductor substrate showing the manufacturing method of the n channel MIS transistor and the p channel MIS transistor subsequent to FIG. 10;

FIG. 12 is a graph showing the relation between the Pt silicide films formed with the different Pt/Si ratios and the flat band voltage (on which the work function of the gate electrode is directly reflected) of the MIS capacitor having a gate electrode composed of the Pt silicide film;

FIG. 13 is a cross-sectional view of the semiconductor substrate showing the manufacturing method of the n channel MIS transistor and the p channel MIS transistor subsequent to FIG. 11;

FIG. 14 is a cross-sectional view of the semiconductor substrate showing the manufacturing method of the n channel MIS transistor and the p channel MIS transistor subsequent to FIG. 13;

FIG. 15 is a cross-sectional view of a semiconductor substrate showing the manufacturing method of a n channel MIS transistor and a p channel MIS transistor according to another embodiment of the present invention;

FIG. 16 is a cross-sectional view of the semiconductor substrate showing the manufacturing method of the n channel MIS transistor and the p channel MIS transistor subsequent to FIG. 15;

FIG. 17 is a cross-sectional view of the semiconductor substrate showing the manufacturing method of the n channel MIS transistor and the p channel MIS transistor subsequent to FIG. 16;

FIG. 18 is a cross-sectional view of the semiconductor substrate showing the manufacturing method of the n channel MIS transistor and the p channel MIS transistor subsequent to FIG. 17;

FIG. 19 is a cross-sectional view of the semiconductor substrate showing the manufacturing method of the n channel MIS transistor and the p channel MIS transistor subsequent to FIG. 18;

FIG. 20 is a cross-sectional view of the semiconductor substrate showing the manufacturing method of the n channel MIS transistor and the p channel MIS transistor subsequent to FIG. 19;

FIG. 21 is a cross-sectional view of the semiconductor substrate showing the manufacturing method of the n channel MIS transistor and the p channel MIS transistor subsequent to FIG. 20;

FIG. 22 is a cross-sectional view of the semiconductor substrate showing the manufacturing method of the n channel MIS transistor and the p channel MIS transistor subsequent to FIG. 21;

FIG. 23 is a cross-sectional view of the semiconductor substrate showing the manufacturing method of the n channel MIS transistor and the p channel MIS transistor subsequent to FIG. 22;

FIG. 24 is a cross-sectional view of the semiconductor substrate showing the manufacturing method of the n channel MIS transistor and the p channel MIS transistor subsequent to FIG. 23;

FIG. 25 is a cross-sectional view of the semiconductor substrate showing the manufacturing method of the n channel MIS transistor and the p channel MIS transistor subsequent to FIG. 24; and

FIG. 26 is a cross-sectional view of the semiconductor substrate showing the manufacturing method of the n channel MIS transistor and the p channel MIS transistor subsequent to FIG. 25.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### FIRST EMBODIMENT

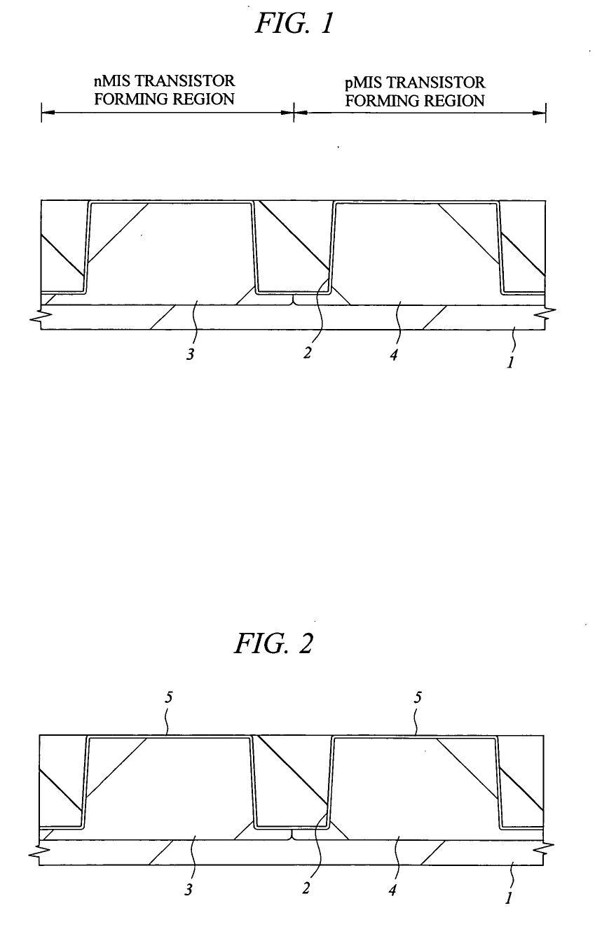

The manufacturing method of a n channel MIS transistor and a p channel MIS transistor according to the first embodiment will be described with reference to FIG. 1 to FIG. 14.

First, as shown in FIG. 1, a device isolation trench 2 is formed in the main surface of the semiconductor substrate (hereinafter, referred to as substrate) 1 made of p type single crystal silicon by using the well-known STI (Shallow Trench Isolation) technology. Thereafter, boron is ion-implanted into a n channel MIS transistor forming region of the substrate 1, and phosphorus is ion-implanted into a p channel MIS transistor forming region of the substrate 1. Subsequently, the impurities (boron and phosphorus) are diffused in the substrate by the thermal treatment of the substrate 1, thereby forming a p type well 3 and a n type well 4 in the main surface of the substrate 1.

Next, impurities for adjusting the threshold voltage of the MIS transistors are ion-implanted into the respective surfaces of the p type well 3 and the n type well 4. Thereafter, as shown in FIG. 2, the gate insulator 5 made of hafnium oxide is formed on each of the surfaces of the p type well 3 and the n type well 4. The hafnium oxide film is deposited by the CVD or the ALD (Atomic Layer Deposition), and the thickness thereof is about 1.5 nm to 4.0 nm.

Note that it is also preferable to form a gate insulator composed of a laminated film of a silicon oxide film and a hafnium oxide film by depositing the hafnium oxide film on the silicon oxide film in the same manner as described above after forming the thin silicon oxide film with a thickness of about 0.4 nm to 1.5 nm on the surface of the substrate 1 by using the well-known wet oxidation method. In this case, it is also preferable to form a gate insulator by introducing nitrogen into the underlying silicon oxide film to form a silicon oxynitride film and then laminating a hafnium oxide film thereon.

In this embodiment, the gate insulator 5 is composed of a hafnium oxide film or a laminated film of a silicon oxide (oxynitride) film and a hafnium oxide film. Alternatively, a hafnium-based insulator other than the hafnium oxide film, for example, Hf—Si—O film, Hf—Si—O—N film, Hf—Al—O film and Hf—Al—O—N film is also available. In addition, it is also possible to use a hafnium-based insulator obtained by introducing oxide such as tantalum oxide, niobium oxide, titanium oxide, zirconium oxide, lanthanum oxide, yttrium oxide and the like into the hafnium-based insulator. Similar to a hafnium oxide film, these hafnium-based insulators have a dielectric constant higher than that of a silicon oxide film and a silicon oxynitride film. Therefore, it is possible to obtain the effect equivalent to the case using a hafnium oxide film. These hafnium-based insulators can be deposited by the CVD, ALD, or sputtering method.

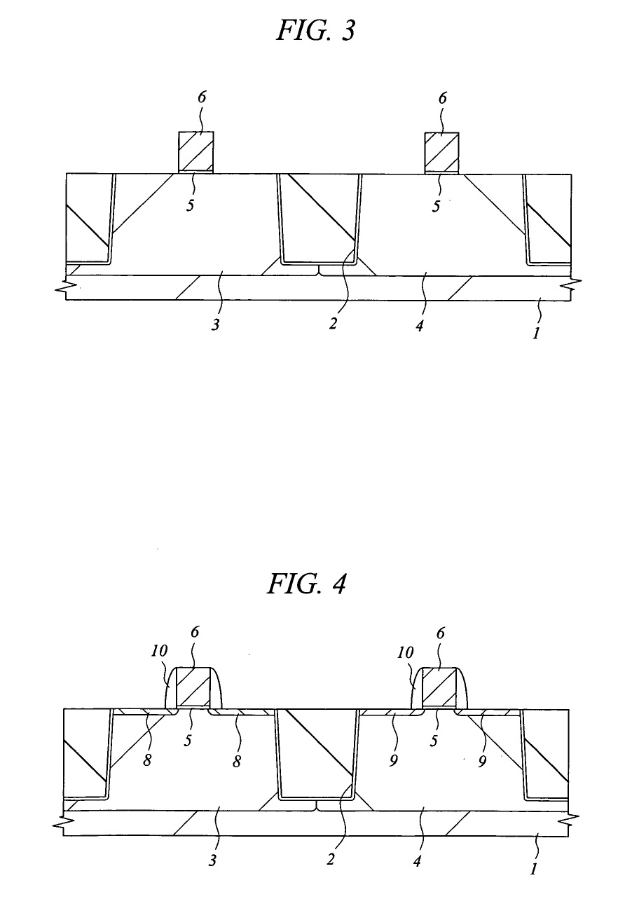

Next, as shown in FIG. 3, a polycrystalline silicon film (or amorphous silicon film) deposited on the substrate 1 by the CVD is patterned to form silicon gate electrodes 6 on each of the gate insulators 5 of the p type well 3 and the n type well 4.

Next, as shown in FIG. 4, phosphorus or arsenic is ion-implanted into the p type well 3 to form n⁻ type semiconductor regions 8, and boron is ion-implanted into the n type well 3 to form p⁻ type semiconductor regions 9. Thereafter, sidewall spacers 10 are formed on each sidewall of the silicon gate electrodes 6. The n⁻ type semiconductor regions 8 are formed in order to form the LDD (Lightly Doped Drain) structure in the n channel MIS transistor. Similarly, the p⁻ type semiconductor regions 9 are formed in order to form the LDD structure in the p channel MIS transistor. The sidewall spacer 10 is formed by depositing a silicon oxide film on the substrate 1 by the CVD and then performing the anisotropic etching of the silicon oxide film.

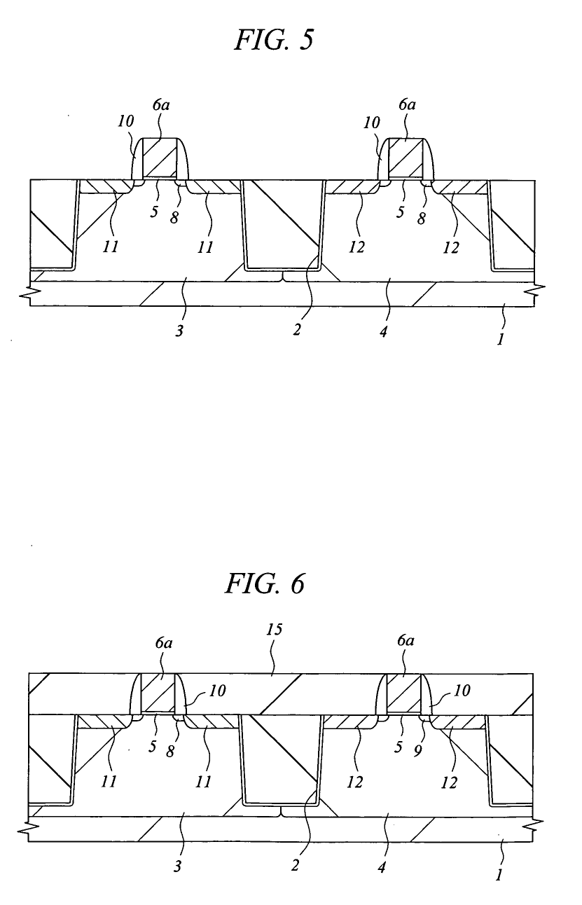

Next, as shown in FIG. 5, phosphorus or arsenic is ion-implanted into the p type well 3 and boron is ion-implanted into the n type well 3. Thereafter, the impurities are diffused by the thermal treatment of the substrate 1, thereby forming n⁺ type semiconductor regions (source, drain) 11 in the p type well 3 and forming p⁺ type semiconductor regions (source, drain) 12 in the n type well 4.

Next, as shown in FIG. 6, after depositing a silicon oxide film 15 on the substrate 1 by the CVD, the surface of the silicon oxide film 15 is polished and planarized by the chemical mechanical polishing. By doing so, the surfaces of the silicon gate electrodes 6 are exposed on the surface of the silicon oxide film 15.

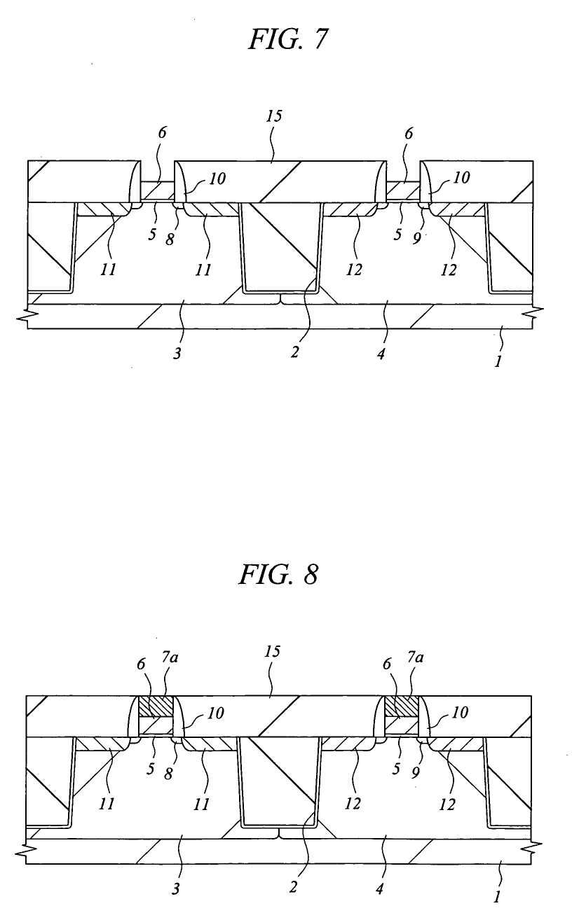

Next, as shown in FIG. 7, the silicon gate electrodes 6 exposed on the surface of the silicon oxide film 15 are dry-etched or wet-etched so that the surfaces of the silicon gate electrodes 6 are retreated below the surface of the silicon oxide film 15.

Alternatively, in the process shown in FIG. 3, a silicon oxide based cap insulator is formed on a polycrystalline silicon film (or amorphous silicon film) and then the cap insulator and the polycrystalline silicon film (or amorphous silicon film) are patterned to form the silicon gate electrodes 6. Thereafter, in the process shown in FIG. 7, the cap insulators exposed on the surface of the silicon oxide film 15 are etched. In this manner, the difference in height between the surface of the silicon gate electrodes 6 and the surface of the silicon oxide film 15 can be made. In this case, in order to prevent the sidewall spacer 10 and the silicon oxide film 15 from being etched in the etching of the cap insulator, a silicon nitride film is used to form the sidewall spacer 10, and silicon oxide based insulators each having different etching selectivity are used to constitute the silicon oxide film 15 and the cap insulator.

Next, as shown in FIG. 8, a Pt film 7a is deposited on the substrate 1 by the sputtering method and then the surface of the Pt film 7a is polished by the chemical mechanical polishing until the surface of the silicon oxide film 15 is exposed. By doing so, the Pt film 7a is left only on the silicon gate electrodes 6. At this time, the amount of the silicon gate electrode 6 to be removed is set in advance so that the thickness of the silicon gate electrode 6 becomes almost equal to that of the Pt film 7a. More specifically, the thickness ratio therebetween is set so that the number of Si atoms contained in the silicon gate electrode 6 becomes almost equal to that of the Pt atoms contained in the Pt film 7a on the silicon gate electrode 6.

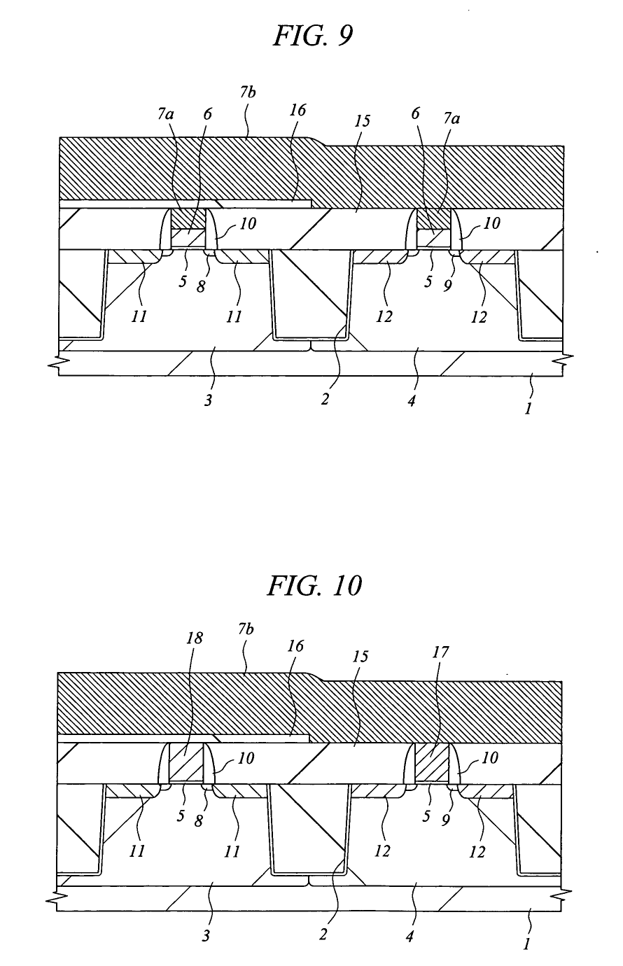

Next, as shown in FIG. 9, the silicon nitride film 16 deposited on the substrate 1 by the CVD is patterned. By doing so, the Pt film 7a on the side of the p type well 3 is covered with the silicon nitride film 16, and the Pt film 7a on the side of the n type well 4 is exposed.

Next, after depositing a Pt film 7b on the substrate 1 by the sputtering method, the substrate 1 is heated to a certain temperature (Tₛᵢ₁), for example, 400 to 600° C. By doing so, as shown in FIG. 10, the silicon gate electrode 6 reacts with the Pt films 7a and 7b on the side of the n type well 4, and a gate electrode 17 made of Pt silicide which is the compound thereof is formed. As described above, since the thickness of the silicon gate electrode 6 is almost equal to that of the Pt film 7a, the total thickness of the Pt film 7a and the Pt film 7b is larger than that of the silicon gate electrode 6. More specifically, the number of Pt atoms contained in the two layers of the Pt film 7a and the Pt film 7b is larger than the number of Si atoms contained in the silicon gate electrode 6. Therefore, in the Pt silicide film (gate electrode 17) formed by the reaction of the silicon gate electrode 6 and the Pt films 7a and 7b, the ratio of the Si atoms to the Pt atoms is less than 1 (PtSiₓ: x<1) in the vicinity of the region in contact with the gate insulator 5.

Meanwhile, on the side of the p type well 3, since the silicon nitride film 16 is interposed between the Pt film 7a and the Pt film 7b, the silicon gate electrode 6 reacts with only the Pt film 7a, and a gate electrode 18 made of Pt silicide which is the compound thereof is formed. As described above, the number of Si atoms contained in the silicon gate electrode 6 is almost equal to the number of Pt atoms contained in the Pt film 7a. Therefore, in the Pt silicide film formed by the reaction of the silicon gate electrode 6 and the Pt film 7a, the ratio of the Si atoms to the Pt atoms is almost equal to 1 (PtSiₓ: x=1) in the vicinity of the region in contact with the gate insulator 5.

As described above, since the thickness of the Pt film which reacts with the silicon gate electrode 6 on the side of the n type well 4 is larger than that on the side of the p type well 3, the gate electrode 18 formed on the side of the p type well 3 is the Pt silicide film in which the ratio of Pt and Si is almost equal to each other in the vicinity of the region in contact with the gate insulator 5, and the gate electrode 17 formed on the side of the n type well 4 is the Pt silicide film in which the ratio of Pt is larger than that of Si in the vicinity of the region in contact with the gate insulator 5.

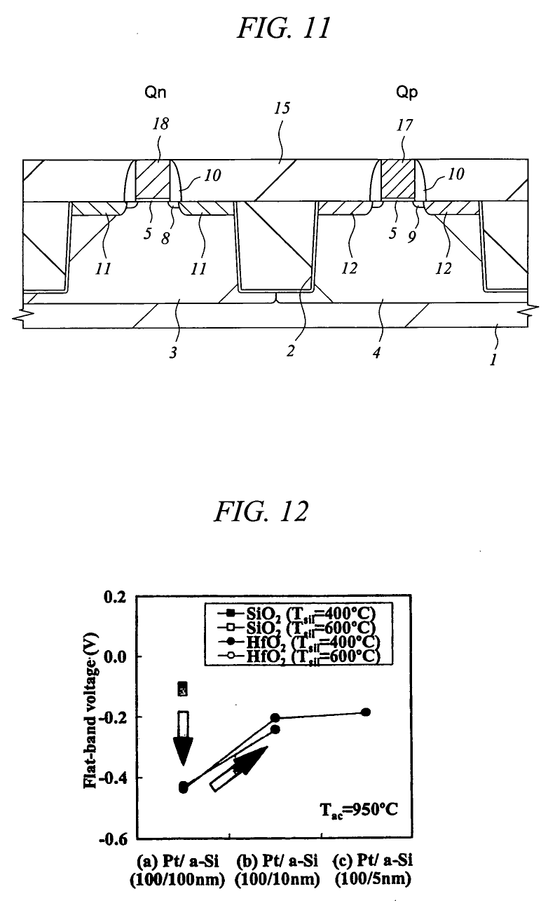

Next, as shown in FIG. 11, the unreacted Pt film 7b is removed by the wet etching using strong acid or the chemical mechanical polishing. Subsequently, the silicon nitride film 16 is removed by the wet etching using the thermal phosphoric acid, thereby exposing the surfaces of the gate electrodes 17 and 18 composed of two types of Pt silicide films. Through the process as described above, the n channel MIS transistor (Qn) having the gate electrode 18 composed of the Pt silicide film in which the ratio of Si to Pt is approximately 1 in the vicinity of the region in contact with the gate insulator 5 is formed on the side of the p type well 3. Also, the p channel MIS transistor (Qp) having the gate electrode 17 composed of the Pt silicide film in which the ratio of Pt is larger than that of Si in the vicinity of the region in contact with the gate insulator 5 is formed on the side of the n type well 4.

FIG. 12 is a graph showing the relation between the Pt/Si ratio at the time when the Pt silicide films with the different Pt/Si ratios are used to form the gate electrode and the work function of the gate electrodes composed of the Pt silicide films in the cases where a silicon oxide film and a hafnium oxide film are used to form the gate insulator. In FIG. 12, the horizontal axis represents the thickness ratio of the silicon gate electrode and the Pt film deposited thereon, and the vertical axis represents the flat band voltage (V_{FB}) of the gate electrode composed of the Pt silicide film, respectively. Also, Tₛᵢ₁ in FIG. 12 denotes the silicide reaction temperature and T_{ac} denotes the annealing temperature at which the impurities of the source and drain are activated.

As is apparent from the graph, when the gate insulator is changed from the silicon oxide film to the hafnium oxide film, the flat band voltage (V_{FB}) of the gate electrode composed of the Pt silicide film is reduced due to the Fermi level pinning. However, when the thickness ratio of Pt film to the silicon gate electrode is gradually increased, the reduction of the flat band voltage (V_{FB}) can be suppressed. More specifically, the reduction of the flat band voltage (V_{FB}) can be suppressed more when the Pt silicide film with the larger ratio of Pt to Si is used.

For example, when a Pt film with a thickness of 100 nm is deposited on a silicon gate electrode with a thickness of 100 nm to form a Pt silicide film, the flat band voltage (V_{FB}) is −0.4 V. On the other hand, when a Pt film with a thickness of 100 nm is deposited on a silicon gate electrode with a thickness of 10 nm to form a Pt silicide film, the flat band voltage (V_{FB}) is −0.2 V. Therefore, in the case where the Pt silicide film formed by depositing a Pt film with a thickness of 100 nm on a silicon gate electrode with a thickness of 10 nm is used for the gate electrode 17 of the p channel MIS transistor (Qp), the threshold voltage of the p channel MIS transistor (Qp) can be reduced by 0.2 V.

The thickness of the Pt film 7b on the silicon gate electrode 6 formed on the side of the n type well 4 is set so that the total thickness of the two Pt films 7a and 7b becomes three times or more, more preferably, fifth times or more as large as that of the silicon gate electrode 6. As described above, since the thickness of the Pt film 7a is almost equal to that of the silicon gate electrode 6, the thickness of the Pt film 7b is set so as to be twice or more, more preferably, four times or more as large as that of the silicon gate electrode 6. By doing so, it is possible to realize the p channel MIS transistor (Qp) with a practical threshold voltage.

Also, when the silicon gate electrode 6 is removed so that the surface of the silicon gate electrode 6 is retreated below the surface of the silicon oxide film 15 in the process shown in FIG. 7, it is also preferable to make the thickness of the silicon gate electrode 6 on the side of the n type well 4 smaller than that on the side of the p type well 3. By doing so, it is possible to easily increase the thickness ratio of the Pt film (7a, 7b) to the thickness of the silicon gate electrode 6 formed on the side of the n type well 4.

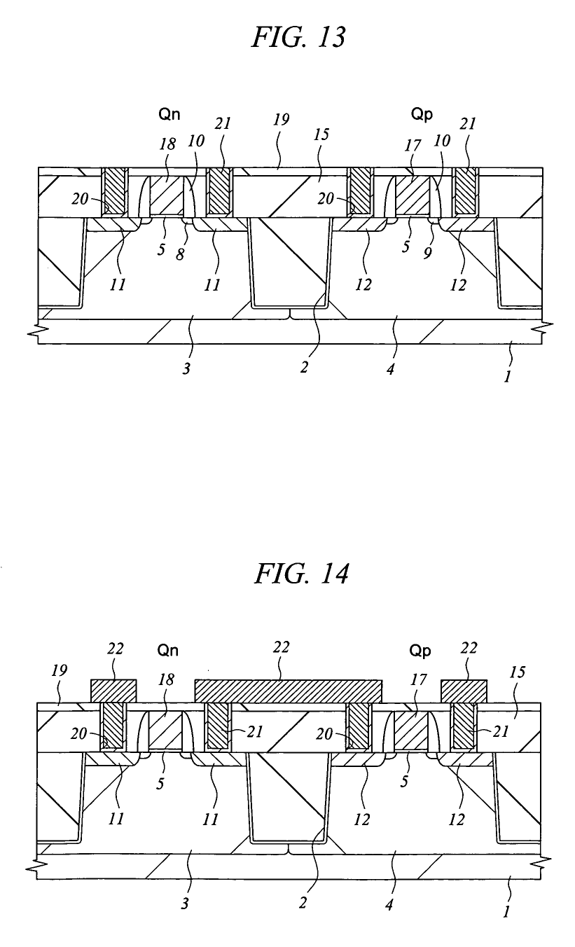

Next, as shown in FIG. 13, after a silicon oxide film 19 is deposited on the silicon oxide film 15 by the CVD and contact holes 20 are formed in the silicon oxide film 19 and the silicon oxide film 15 by the dry etching using a photoresist film as a mask, plugs 21 are formed in the contact holes 20. The plugs 21 are formed in the following manner. That is, after depositing a titanium nitride (TiN) film and a tungsten (W) film on the silicon oxide film 19 and in the contact holes 20 by the sputtering method, the TiN film and the W film on the silicon oxide film 19 are removed by the chemical mechanical polishing.

Next, as shown in FIG. 14, metal interconnects 22 are formed on the silicon oxide film 19. The metal interconnects 22 are formed in the following manner. That is, after depositing a metal film such as a W film or an Al metal alloy film on the silicon oxide film 19 by the sputtering method, the metal film is patterned by the dry etching using a photoresist film as a mask.

In this embodiment, the Pt silicide film is formed through the solid-phase reaction between the silicon gate electrode 6 and the Pt film (7a, 7b). However, the same effects can be achieved also when a Ni film, a Ru film or an Ir film is used instead of a Pt film.

### SECOND EMBODIMENT

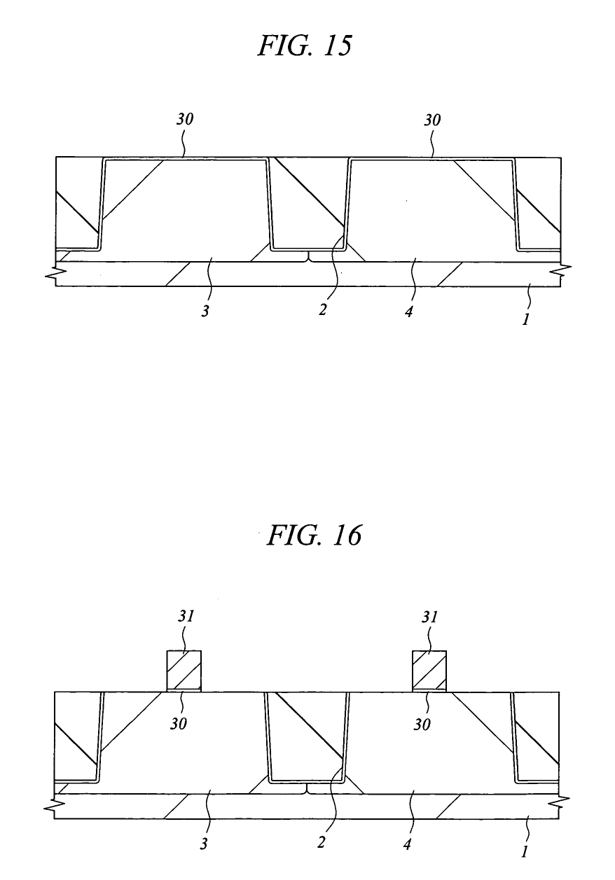

The manufacturing method of a n channel MIS transistor (Qn) and a p channel MIS transistor (Qp) according to the second embodiment will be described with reference to FIG. 15 to FIG. 25.

First, by the same method as described in the first embodiment with reference to FIG. 1, the device isolation trenches 2, the p type well 3 and the n type well 4 are formed in the main surface of the substrate 1. Subsequently, impurities for adjusting the threshold voltage of the MIS transistors are ion-implanted into the surfaces of the p type well 3 and the n type well 4. Next, as shown in FIG. 15, a gate insulator 30 made of silicon oxide is formed on each of the surfaces of the p type well 3 and the n type well 4 by the thermal treatment of the substrate 1.

Next, as shown in FIG. 16, after depositing a polycrystalline silicon film (or amorphous silicon film) on the substrate 1 by the CVD, the polycrystalline silicon film is patterned by the dry etching using a photoresist film as a mask. By doing so, a silicon gate electrode 31 is formed on each of the gate insulators 30 of the p type well 3 and the n type well 4. The silicon gate electrodes 31 are dummy gate electrodes to be removed from the substrate 1 in the process described later. Therefore, the material thereof is not limited to silicon and various kinds of insulating materials and metal materials with the high etching selectivity to the silicon oxide based insulator can be used.

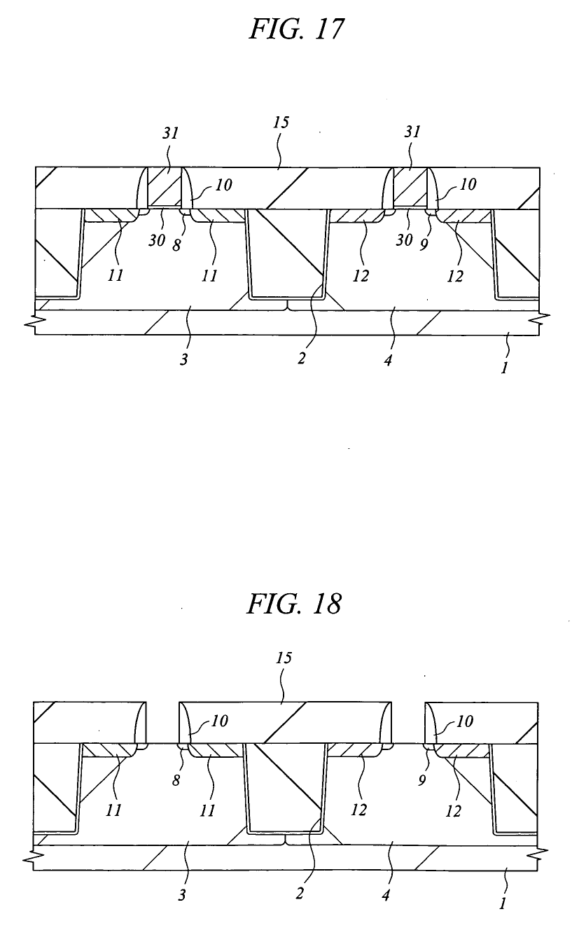

Next, as shown in FIG. 17, the n⁻ type semiconductor regions 8, the p⁻ type semiconductor regions 9, the sidewall spacers 10, the n⁺ type semiconductor regions (source, drain) 11 and the p⁺ type semiconductor regions (source, drain) 12 are sequentially formed through the same process as described in the first embodiment with reference to FIG. 4 to FIG. 6. Subsequently, the surface of the silicon oxide film 15 deposited on the substrate 1 is polished and planarized by the chemical mechanical polishing. By doing so, the surfaces of the silicon gate electrodes 31 are exposed on the surface of the silicon oxide film 15.

Next, as shown in FIG. 18, the silicon gate electrodes 31 and the underlying gate insulators 30 are etched and removed to expose the surface of the substrate 1 (p type well 3, n type well 4).

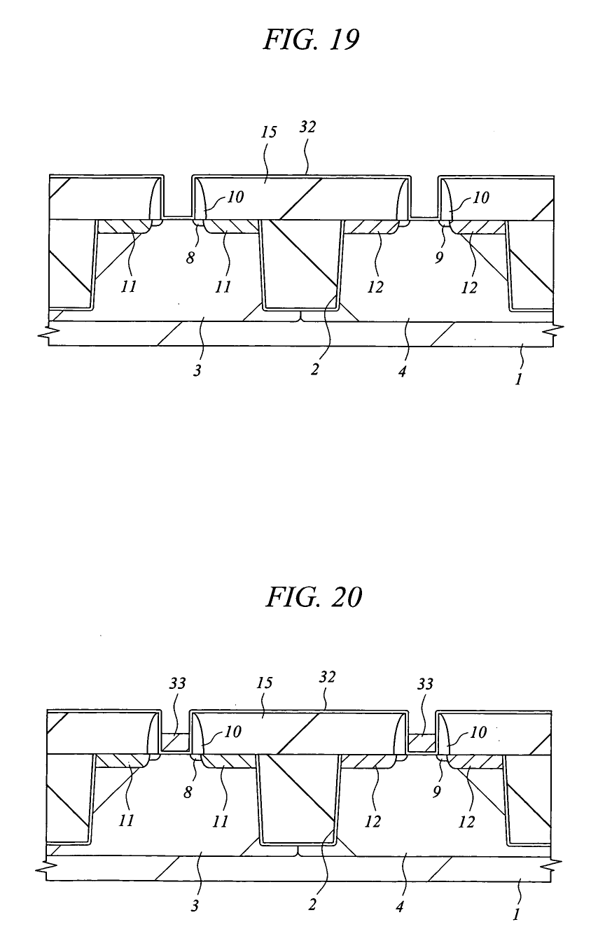

Next, as shown in FIG. 19, a gate insulator 32 is formed on the substrate 1. Any one of various kinds of hafnium-based insulating materials exemplified in the first embodiment is used for the gate insulator 32, and the gate insulator 32 is deposited by the CVD, the ALD, or the sputtering method so as have a small thickness which does not fill the inside of the trenches formed by the removal of the silicon gate electrodes 31 and the gate insulators 30.

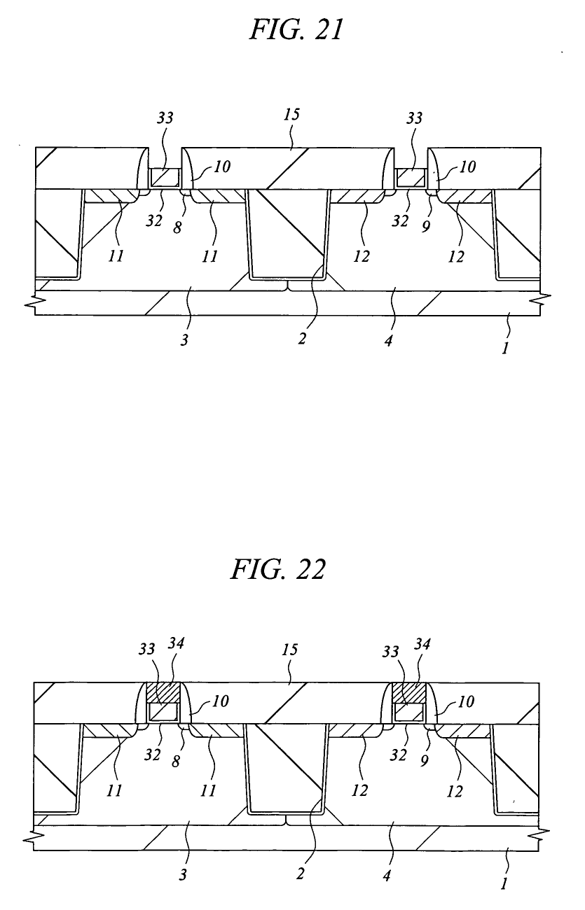

Next, as shown in FIG. 20, after depositing a polycrystalline silicon film (or amorphous silicon film) 33 on the substrate 1 by the CVD, the polycrystalline silicon film 33 is etched so that the surface thereof is retreated below the surface of the silicon oxide film 15. Subsequently, as shown in FIG. 21, the silicon gate electrode 31 in the region not covered with the polycrystalline silicon film 33 is etched and removed.

Next, as shown in FIG. 22, after depositing a Ni (nickel) film 34 on the substrate 1 by the sputtering method, the surface of the Ni film 34 is polished by the chemical mechanical polishing until the surface of the silicon oxide film 15 is exposed. By doing so, the Ni film 34 is left on only the polycrystalline silicon films 33. At this time, the thickness of the polycrystalline silicon film 33 is set in advance so that the thickness of the polycrystalline silicon film 33 becomes almost equal to that of the Ni film 34. More specifically, the thickness ratio therebetween is set so that the number of Si atoms contained in the polycrystalline silicon film 33 becomes almost equal to that of the Ni atoms contained in the Ni film 34.

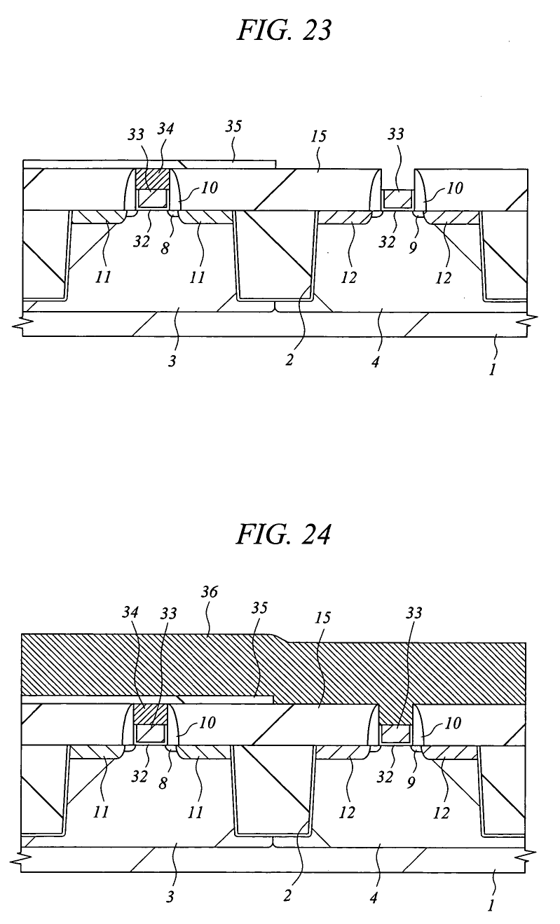

Next, as shown in FIG. 23, the silicon nitride film 35 deposited on the substrate 1 by the CVD is patterned. By doing so, the Ni film 34 on the side of the p type well 3 is covered with the silicon nitride film 35. Thereafter, the Ni film 34 on the side of the n type well 4 is etched and removed, and thus, the polycrystalline silicon film 33 on the side of the n type well 4 is exposed.

Next, as shown in FIG. 24, a Pt film 36 is deposited on the substrate 1 by the sputtering method. At this time, similar to the Pt film 7b in the first embodiment, the thickness of the Pt film 35 on the polycrystalline silicon film 33 on the side of the n type well 4 is set so as to be three times or more, more preferably, fifth times or more as large as that of the polycrystalline silicon film 33.

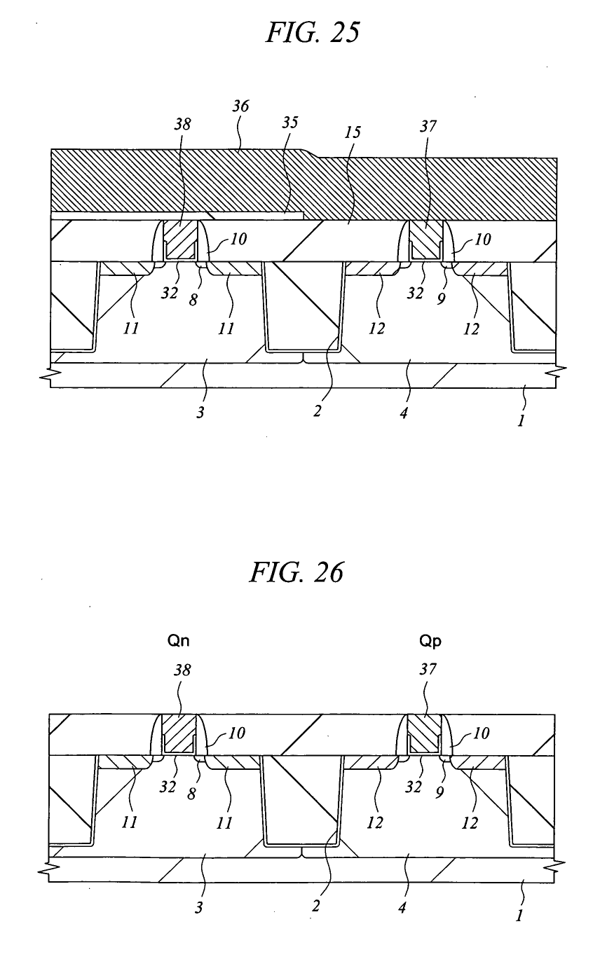

Next, the substrate 1 is heated to about 400 to 600° C. By doing so, as shown in FIG. 25, the polycrystalline silicon film 33 reacts with the Pt film 36 thereon on the side of the n type well 4, and a gate electrode 37 made of Pt silicide which is the compound thereof is formed. As described above, since the thickness of the Pt film 36 is larger than that of the polycrystalline silicon film 33, the number of Pt atoms contained in the Pt film 36 is larger than that of Si atoms contained in the polycrystalline silicon film 33. Therefore, in the Pt silicide film (gate electrode 37) formed by the reaction of the polycrystalline silicon film 33 and the Pt films 36, the ratio of Si to Pt is less than 1 (PtSiₓ: x<1) in the vicinity of the region in contact with the gate insulator 32.

Meanwhile, on the side of the p type well 3, since the silicon nitride film 35 is interposed between the Ni film 34 and the Pt film 36, the polycrystalline silicon film 33 reacts with only the Ni film 34, and a gate electrode 38 made of Nt silicide which is the compound thereof is formed. As described above, the number of Si atoms contained in the polycrystalline silicon film 33 is almost equal to the number of Ni atoms contained in the Ni film 34. Therefore, in the Ni silicide film formed by the reaction of the polycrystalline silicon film 33 and the Ni film 34, the ratio of Si to Ni is approximately 1 (NtSiₓ: x=1) in the vicinity of the region in contact with the gate insulator 32.

Next, as shown in FIG. 26, the unreacted Pt film 36 is removed by the wet etching using strong acid or the chemical mechanical polishing. Subsequently, the silicon nitride film 35 is removed by the wet etching using the thermal phosphoric acid, thereby exposing the surfaces of the gate electrodes 37 and 38. Through the process as described above, the n channel MIS transistor (Qn) having the gate electrode 38 composed of the Ni silicide film in which the ratio of Si to Ni is approximately 1 in the vicinity of the region in contact with the gate insulator 32 is formed on the side of the p type well 3. Also, the p channel MIS transistor (Qp) having the gate electrode 37 composed of the Pt silicide film in which the ratio of Pt is larger than that of Si in the vicinity of the region in contact with the gate insulator 32 is formed on the side of the n type well 4. Since the subsequent process is the same as that described in the first embodiment with reference to FIG. 13 and FIG. 14, the description thereof will be omitted.

The second embodiment is characterized in that a Ni silicide film is used to form the gate electrode 38 of the n channel MIS transistor (Qn). When a Pt silicide film is used to form the gate electrode 17 of the n channel MIS transistor (Qn) like in the first embodiment, the flat band voltage (V_{FB}) of the n channel MIS transistor (Qn) is −0.4 V. Meanwhile, when a Ni silicide film is used to form the gate electrode 38 of the n channel MIS transistor (Qn), the flat band voltage (V_{FB}) of the n channel MIS transistor (Qn) is −0.6 V. Therefore, the threshold voltage of the n channel MIS transistor (Qn) can be further reduced by that much.

Also, according to the manufacturing method of this embodiment, since the gate insulator 32 is formed in the process just before the process of depositing the polycrystalline silicon film 33, the contamination and the degradation of the gate insulator 32 can be prevented, and the reliability of the n channel MIS transistor (Qn) and the p channel MIS transistor (Qp) can be improved.

In this embodiment, a Ni silicide film is used to form the gate electrode 38 of the n channel MIS transistor (Qn) and a Pt silicide film is used to form the gate electrode 37 of the p channel MIS transistor (Qp). However, the same effects can be achieved also when a Ti silicide film is used to form the gate electrode 38 of the n channel MIS transistor (Qn) and a Pt silicide film is used to form the gate electrode 37 of the p channel MIS transistor (Qp). Note that, when a Ti silicide film is used to form the gate electrode 38 of the n channel MIS transistor (Qn), the ratio of Si to Ti can be either 1 or less than 1.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be applied to the semiconductor device in which a n channel MIS transistor and a p channel MIS transistor each having a Hf-based gate insulator are used to form a CMOS circuit.

What is claimed is:

1. A semiconductor device in which a n channel MIS transistor is formed in a first region on a main surface of a semiconductor substrate made of single crystal silicon and a p channel MIS transistor is formed in a second region on said main surface,
wherein each of said n channel MIS transistor and said p channel MIS transistor has a gate electrode composed of a metal silicide film formed by solid-phase reaction of a silicon film and a metal film on a gate insulator mainly containing hafnium-based oxide,
said metal silicide film constituting the gate electrode of said n channel MIS transistor has a ratio of silicon atoms to metal atoms of approximately 1 in the vicinity of a region in contact with said gate insulator, and
said metal silicide film constituting the gate electrode of said p channel MIS transistor has a ratio of silicon atoms to metal atoms lower than said ratio of said n channel MIS transistor in the vicinity of a region in contact with said gate insulator.

2. The semiconductor device according to claim 1,
wherein said metal film is one of the metal films selected from a group including a platinum film, a nickel film, a ruthenium film and a iridium film.

3. The semiconductor device according to claim 2,
wherein said metal film is a platinum film.

4. A semiconductor device in which a n channel MIS transistor is formed in a first region on a main surface of a semiconductor substrate made of single crystal silicon and a p channel MIS transistor is formed in a second region on said main surface,
wherein said n channel MIS transistor has a gate electrode composed of a first metal silicide film formed by solid-phase reaction of a silicon film and a first metal film on a gate insulator mainly containing hafnium-based oxide,
said p channel MIS transistor has a gate electrode composed of a second metal silicide film formed by solid-phase reaction of a silicon film and a second metal film on a gate insulator mainly containing hafnium-based oxide,
said first metal silicide film constituting the gate electrode of said n channel MIS transistor has a ratio of silicon atoms to first metal atoms of approximately 1 in the vicinity of a region in contact with said gate insulator, and
said second metal silicide film constituting the gate electrode of said p channel MIS transistor has a ratio of silicon atoms to second metal atoms less than 1 in the vicinity of a region in contact with said gate insulator.

5. The semiconductor device according to claim 4,
wherein said first metal film is one of the metal films selected from a group including a platinum film, a nickel film, a ruthenium film and a iridium film, and said second metal film is the metal film made of an element selected from said group and different from that constituting said first metal film.

6. The semiconductor device according to claim 5,
wherein said first metal film is a nickel film, and said second metal film is a platinum film.

7. The semiconductor device according to claim 1,
wherein said gate insulator mainly contains at least one of hafnium oxides selected from a group including HfO, Hf—Si—O, Hf—Si—O—N, Hf—Al—O and Hf—Al—O—N.

8. A method of manufacturing a semiconductor device in which a n channel MIS transistor is formed in a first region on a main surface of a semiconductor substrate made of single crystal silicon and a p channel MIS transistor is formed in a second region on said main surface, said method comprising the steps of:
(a) forming a gate insulator mainly containing hafnium oxide on the main surface of said semiconductor substrate;
(b) forming a first silicon gate electrode of said n channel MIS transistor on said gate insulator in said first region and forming a second silicon gate electrode of said p channel MIS transistor on said gate insulator in said second region;
(c) depositing a first insulator with a thickness larger than that of said first and second silicon gate electrodes on the main surface of said semiconductor substrate, and then, planarizing a surface of said first insulator, thereby exposing each surface of said first and second silicon gate electrodes on the surface of said first insulator;
(d) etching each of said first and second silicon gate electrodes exposed on the surface of said first insulator, thereby retreating the surfaces of said first and second silicon gate electrodes below the surface of said first insulator;
(e) after said step (d), laminating a metal film with a thickness almost equal to that of said first silicon gate electrode on each of said first and second silicon gate electrodes;
(f) selectively covering said metal film laminated on said first silicon gate electrode with a second insulator, and then, further laminating a metal film on said metal film laminated on said second silicon gate electrode; and
(g) heating said semiconductor substrate to induce the solid phase reaction between said first and second silicon gate electrodes and said metal film, thereby forming a gate electrode of said n channel MIS transistor composed of a metal silicide film having a ratio of silicon atoms to metal atoms of approximately 1 in the vicinity of a region in contact with said gate insulator, and forming a gate electrode of said p channel MIS transistor composed of a metal silicide film having a ratio of silicon atoms to metal atoms lower than said ratio of said n MIS transistor in the vicinity of a region in contact with said gate insulator.

9. The method of manufacturing a semiconductor device according to claim 8,
wherein the thickness of said metal film laminated in said step (f) is twice or more as large as that of said metal film laminated in said step (e).

10. The method of manufacturing a semiconductor device according to claim 9,
wherein the thickness of said metal film laminated in said step (f) is four times or more as large as that of said metal film laminated in said step (e).

11. The method of manufacturing a semiconductor device according to claim 8,
wherein a total thickness of said metal film laminated in said step (e) and said metal film laminated in said step (f) is ten times or more as large as that of said second silicon gate electrode.

12. The method of manufacturing a semiconductor device according to claim 8,
wherein said metal film is one of the metal films selected from a group including a platinum film, a nickel film, a ruthenium film and a iridium film.

13. The method of manufacturing a semiconductor device according to claim 12,
wherein said metal film is a platinum film.

14. The method of manufacturing a semiconductor device according to claim 8,
wherein said gate insulator is formed just before said step (b).

15. The method of manufacturing a semiconductor device according to claim 8,
wherein said gate insulator mainly contains at least one of hafnium oxides selected from a group including HfO, Hf—Si—O, Hf—Si—O—N, Hf—Al—O and Hf—Al—O—N.

16. The method of manufacturing a semiconductor device according to claim 8,
wherein said step (e) includes the steps of:
(e-1) laminating a first metal film on said first silicon gate electrode; and
(e-2) laminating a second metal film on said second silicon gate electrode,
wherein said metal film laminated on said second metal film in said step (f) is a second metal film,
said first metal film and said second metal film are made of respectively different elements, and
the thickness of said second metal film is three times or more as large as that of said second silicon gate electrode.

17. The method of manufacturing a semiconductor device according to claim 16,
wherein said first metal film is a nickel film or a titanium film, and said second metal film is a platinum film.
